(19) United States
(12) Patent Application Publication
(10) Pub. No.: US 2014/0054756 A1
(43) Pub. Date: Feb. 27, 2014

(54) ANTI SPACER PROCESS AND SEMICONDUCTOR STRUCTURE GENERATED BY THE ANTI SPACER PROCESS

(71) Applicants: MICHAEL HYATT, Boise, ID (US); Richard Housley, Boise, ID (US); ANTON DEVILLIERS, Boise, ID (US)

(72) Inventors: MICHAEL HYATT, Boise, ID (US); Richard Housley, Boise, ID (US); ANTON DEVILLIERS, Boise, ID (US)

(21) Appl. No.: 13/593,503

(22) Filed: Aug. 23, 2012

(51) Int. Cl. H01L 21/31; H01L 29/02

(52) U.S. Cl. 257/635; 438/694; 257/E29.002; 257/E21.24

(57) ABSTRACT

An anti spacer process, which comprises: (a) providing a resist layer including a non-uniform shape; (b) coating a target layer above the resist layer; (c) providing anti spacer trenches (spa) between the target layer and the resist layer; and (d) connecting at least part of the anti spacer trenches (spa) together to isolate a first part of the target layer and a second part of the target layer.

### BACKGROUND OF THE INVENTION

1. Field of the Invention

The present invention relates to an anti spacer process and a semiconductor structure generated by the anti spacer process, and particularly relates to an anti spacer process using selective pattern modification to eliminate the need for a cut mask, and a semiconductor structure generated by the anti spacer process.

2. Description of the Prior Art

Pitch doubling technique are processing standards for both DRAM and NAND processing. Anti spacer processing is a method that can be used for pitch doubling process. FIG. 1-FIG. 4 illustrate the steps of a conventional anti spacer processing. Each of the diagrams in FIG. 1-FIG. 4 includes a FIG. (a) and a FIG. (b). Each FIG. (a) indicates a top view and each FIG. (b) indicates a cross-section view, in the direction indicated by the dotted line X in each FIG. (a).

FIG. 1(a) illustrates a top view of a resist layer L1, which is an ADI pattern (After Develop Inspect), and FIG. 1(b) illustrates a cross section view of FIG. 1(a). In FIG. 2(a), acid coating, rinsing, and baking is provided over L1 pattern, such that acid load AC is provided over the resist layer L1. Based on FIG. 2 (b), it can be found that full surface of the resist pattern L1 receives acid but the core material Cor below upper surface does not receive acid due to limited diffusion of the acid during the bake. The Cor area is indicated by marks different from that of the acid load AC in FIG. 2(a). Please note the acid load AC covers all the surfaces the whole core material Cor but such situation is only shown in FIG. 2(b) but not in FIG. 2(a). In FIGS. 3(a) and 3(b), a layer L2 is shown coated over L1 pattern. L2 is a material different from that of L1, whose properties allow it to coat over L1 without adversely affecting the L1 patterns. In FIG. 4(a) and FIG. 4(b), the upper section of the target layer L2 and the acid load AC are developed out, such that anti spacer (or named anti spacer trench) Spa, which indicates space area between L1 and L2, is formed. However, such process includes some disadvantages. For example, a cut mask M is required to disconnect features formed around the ends of the target pattern L2, such as the target portion Tp shown in FIG. 4(a).Therefore, extra cost for the cut mask and extra steps are needed.

### SUMMARY OF THE INVENTION

Therefore, one objective of the present invention is to provide an anti spacer process that needs no cut mask to cut target features thereof.

Another objective of the present invention is to provide a semiconductor structure generated by the anti spacer process that needs no cut mask.

One embodiment of the present invention discloses an anti spacer process, which comprises: (a) providing a resist layer including a non-uniform shape; (b) coating a target layer above the resist layer; (c) providing anti spacer trenches (spa) between the target layer and the resist layer; and (d) connecting at least part of the anti spacer trenches (spa) together to isolate a first part of the target layer and a second part of the target layer.

Another embodiment of the present invention discloses an anti spacer process, which comprises: (a) providing a resist layer including a non-uniform shape; (b) coating a target layer including a plurality of target features over the resist layer; and (c) isolating the target features via the non-uniform shape, without utilizing a cut mask.

Still another embodiment of the present invention discloses a semiconductor structure, which comprises: a resist layer including a non-uniform shape; and a target layer, including a first part and a second part; wherein anti spacer is provided between the resist layer and the target layer, and the first part and the second part are isolated via the anti spacer.

In view of above-mentioned embodiments, an anti spacer process with self cut ability is provided and a semiconductor structure generated via this anti spacer process are disclosed. Therefore, it is un-necessary to utilize a cut mask or any other process to cut the target feature, thereby the cost can be saved and the complicated steps can be avoided.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1-FIG. 4 are schematic diagrams illustrating a conventional anti spacer process.

FIG. 5-FIG. 8 are schematic diagrams illustrating examples of embodiments that result in self cut ability.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”, such that the term” “include” and “comprise” mean other elements besides those claimed in claims can also be added.

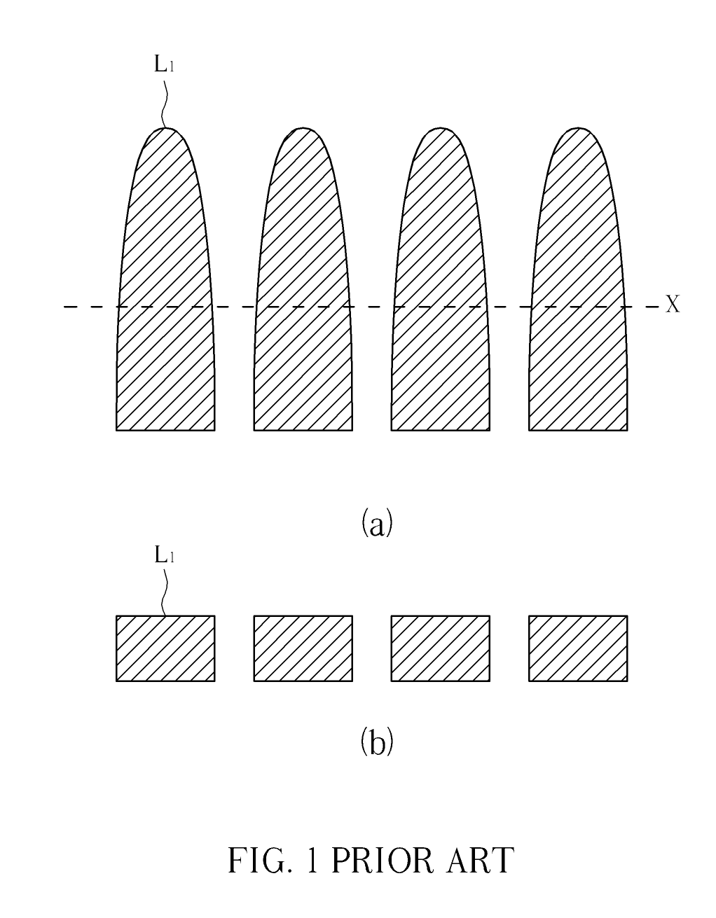

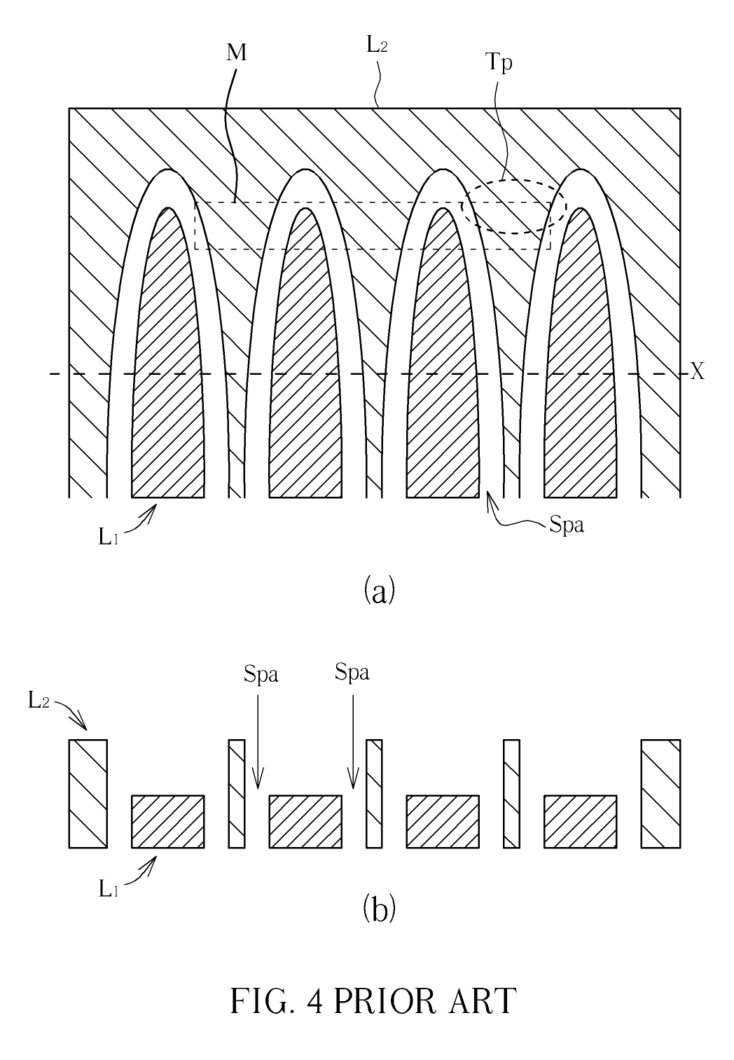

FIG. 5-FIG. 8 are schematic diagrams illustrating an anti spacer process according to the embodiments of the present invention. Cross section views are omitted here for brevity here since they are similar with all FIG. (b) in FIG. 1-FIG. (4). Please jointly refer to FIG. 1-FIG. 4 and FIG. 5-FIG. 8 to understand the present invention more clearly. FIG. 5 illustrates a top view of a resist layer L1. Please note the resist layer L1 shown in FIG. 5 has a non-uniform shape, rather than the uniform shape shown in FIG. 1. Specifically, the resist layer L1 shown in FIG. 5 includes a wide part PW and a narrow part PN. The wide part has a max width W1 larger than the width W2 of the narrow part PN. In this embodiment, the wide part PW is oval-shaped and the narrow part PN is line-shaped. Besides, in FIG. 5 the wide part PW is at the end of the resist layer L1. However, please note the structure disclosed in FIG. 5 is only for example and does not mean to limit the scope of the present invention. Any non-uniform structure that can reach the “self cut” function that will be described as bellow should be included in the scope of the present invention.

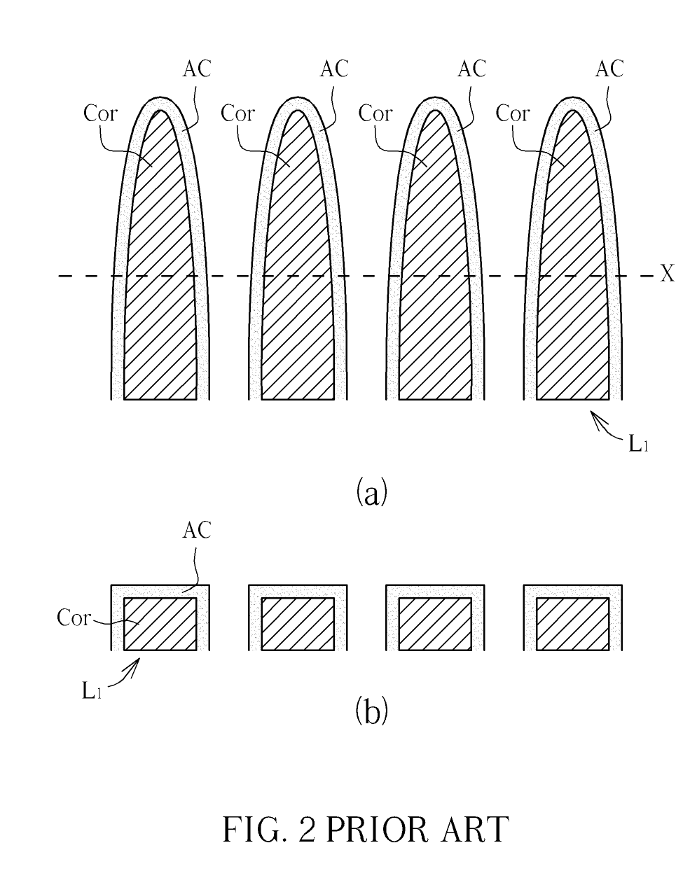

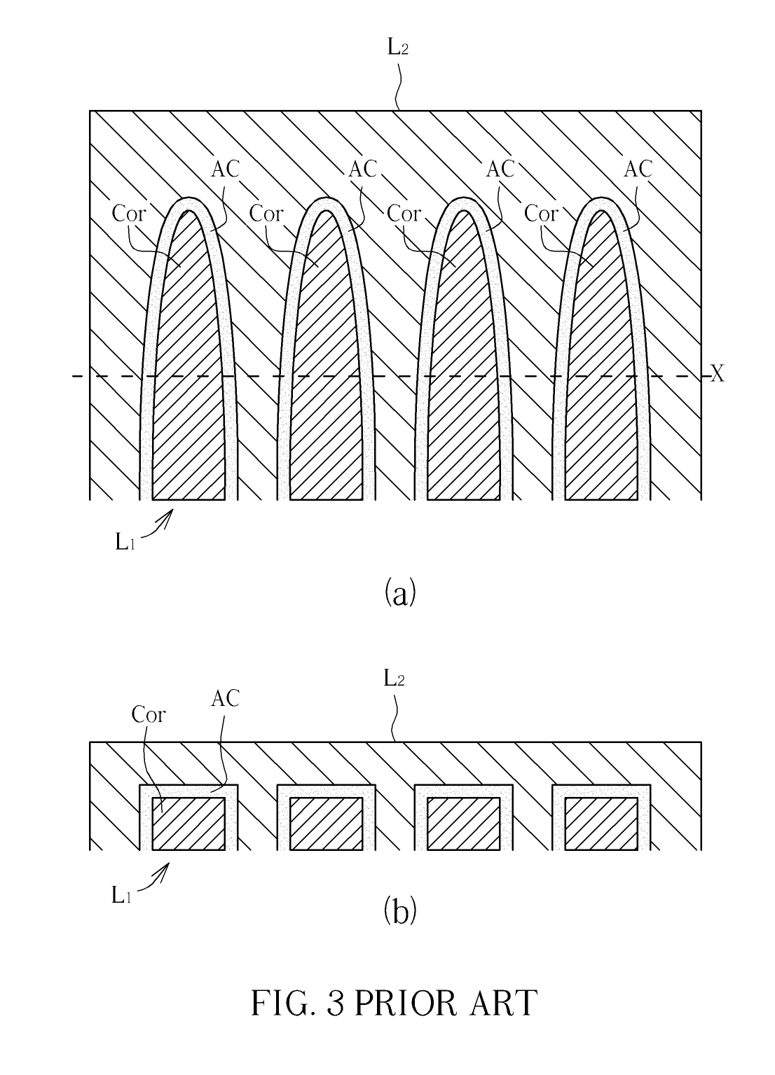

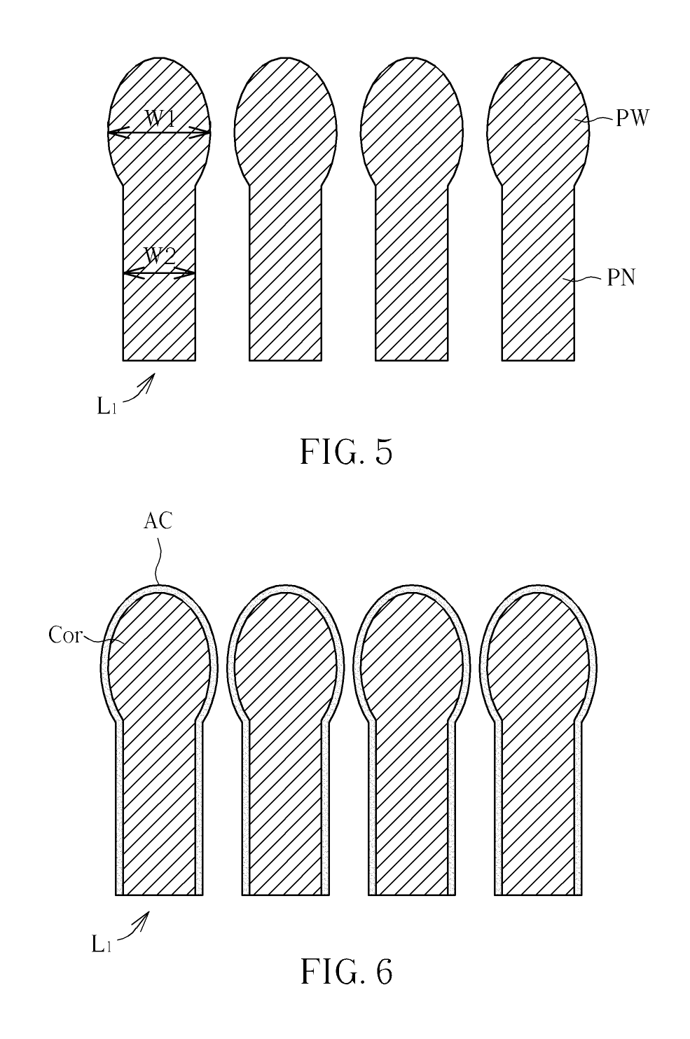

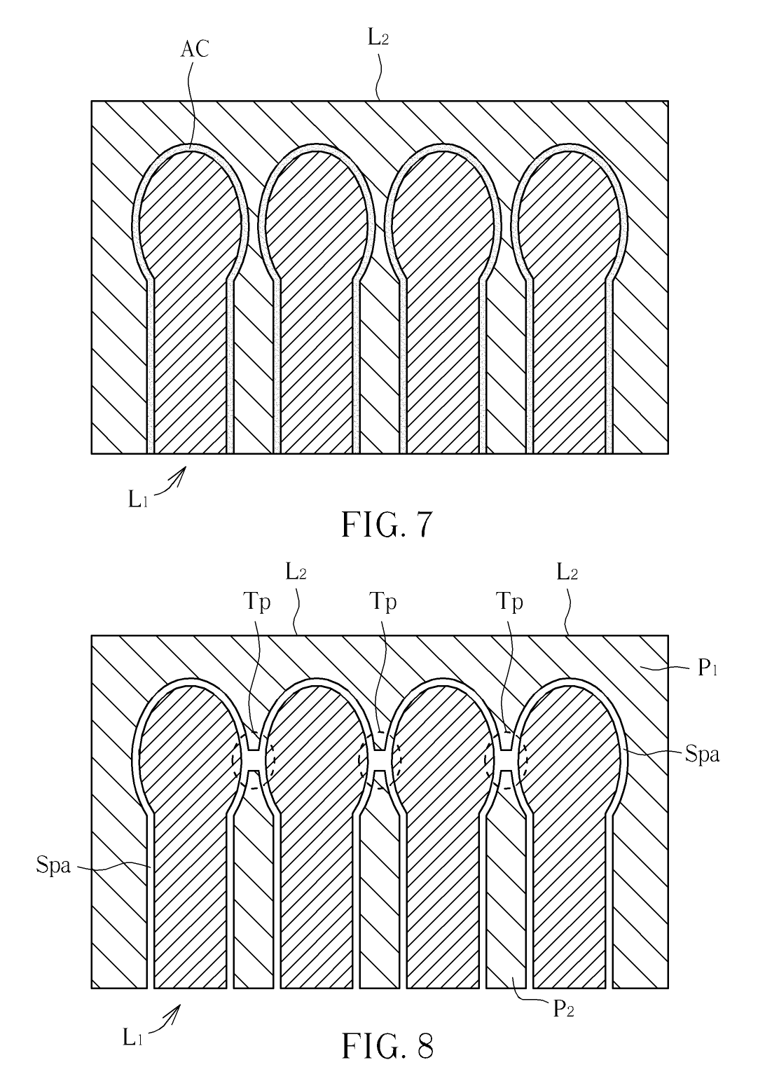

Similar with the operation depicted in FIG. 2(a) and FIG. 2(b), in FIG. 6 acid coating, rinsing, and baking is provided over L1 pattern, such that acid load Ac is provided over the resist layer L1. In FIG. 7, a target layer L2, which is a layer comprised so as to not intermix with or adversely affect the L1 pattern, is coated over L1 pattern, similar with the operation depicted in FIG. 3(a) and FIG. 3(b). In FIG. 8, the upper section of the target layer L2 and the acid load AC are developed out, such that anti spacer Spa is formed between the adjacent resist layer L1 patterns, isolating the areas P1 and P2 by area Tp. Since the resist later L1 includes a non-uniform shape, the target feature Tp is created in the target layer L2 without utilizing a cut mask. The target feature Tp can be formed via various mechanisms. For example, the anti-spacer areas Spa can be directly merged by a particular step to form the target feature Tp. Alternatively, anti-spacer area Spa can be widened during the etching step for removing the acid load AC, such that adjacent anti-spacer areas can be merged together to form the target feature Tp.

In view of the above-mentioned embodiments, the anti spacer process present invention can be summarized as follows: providing a resist layer including a non-uniform shape (L1); coating a target layer above the resist layer (L2); providing anti spacer trenches (spa) between the target layer and the resist layer; connecting at least part of the anti spacer trenches together to isolate a first part (P1 in FIG. 8) of the target layer and a second part (P2 in FIG. 8) of the target layer L2.

Alternatively, the anti spacer process present invention can also be summarized as follows: providing a resist layer including a non-uniform shape (L1); coating a target layer including a plurality of target features (TP in FIG. 8) over the resist layer; and isolating the target features via the non-uniform shape, without utilizing a cut mask.

Additionally, the structure shown in FIG. 8 can be summarized as follows: a semiconductor structure including a resist layer L1, a target layer L2, and anti spacer spa. The resist layer L1 includes a non-uniform shape. The target layer L2 includes a first part P1 and a second part P2 which normally would need separated by a cut mask. In this present invention the Spa area is provided as a result of the invention and the first part P1 and the second part P2 are isolated via the anti spacer spa.

In view of above-mentioned embodiments, an anti spacer process with self cut ability is provided and a semiconductor structure generated via this anti spacer process are disclosed. Therefore, with use of said embodiments it is unnecessary to utilize a cut mask or any other process to cut the target feature, thereby the cost can be saved and the complicated steps can be avoided.

Those skilled in the art will readily observe that numerous modifications and alterations of the device and method may be made while retaining the teachings of the invention. Accordingly, the above disclosure should be construed as limited only by the metes and bounds of the appended claims.

1. An anti spacer process, comprising:
(a) providing a resist layer including a non-uniform shape;
(b) coating a target layer above the resist layer;
(c) providing anti spacer trenches between the target layer and the resist layer; and
(d) connecting at least part of the anti spacer trenches together to isolate a first part of the target layer and a second part of the target layer.

2. The anti spacer process of claim 1, wherein the step (d) directly merges the parts of the anti spacer trenches to connect the parts of the anti spacer trenches together.

3. The anti spacer process of claim 1, further comprising:
(a1) providing acid load over the resist layer, before the step (b) and after the step (a);
wherein the step (c) includes:
(c1) removing the acid load and part of the target layer to form the anti spacer trenches;
wherein the anti spacer trenches are widened during the removal of the acid load such that at least part of the anti spacer trenches can be connected together in the step (d).

4. The anti spacer process of claim 1, wherein the non-uniform shape includes a wide part and a narrow part, where the points at which the anti spacer trenches are connected are closer to the wide part than to the narrow part when the target layer is coated over the resist layer.

5. The anti spacer process of claim 4, wherein the wide part is oval-shaped and the narrow part is line-shaped.

6. The anti spacer process of claim 4, wherein the wide part is provided at the end of the resist layer.

7. An anti spacer process, comprising:
(a) providing a resist layer including a non-uniform shape;
(b) coating a target layer including a plurality of target features over the resist layer; and
(c) isolating the target features via the non-uniform shape, without utilizing a cut mask.

8. The anti spacer process of claim 7, further comprising a step (b1) developing away part of the target layer; wherein the step (b1) is performed after the step (b), such that the anti spacer around the resist layer is generated and merged together thereby the step (c) is performed.

9. The anti spacer process of claim 7, wherein the non-uniform shape includes a wide part and a narrow part, where the target features are closer to the wide part than to the narrow part when the target layer is coated over the resist layer.

10. The pitch doubling process of claim 7, wherein the wide part is oval-shaped and the narrow part is line-shaped.

11. The pitch doubling process of claim 7, wherein the wide part is at the end of the resist layer.

12. A semiconductor structure, comprising:
a resist layer including a non-uniform shape; and
a target layer, including a first part and a second part;
wherein anti spacer is provided between the resist layer and the target layer, and the first part and the second part are isolated via the anti spacer.

13. The semiconductor structure of claim 12, wherein the non-uniform shape includes a wide part and a narrow part, where the locations that the first part and the second part are isolated are closer to the wide part than to the narrow part.

14. The semiconductor structure of claim 13, wherein the wide part is oval-shaped and the narrow part is line-shaped.

15. The pitch doubling process of claim 13, wherein the wide part is at the end of the resist layer.
